(19) United States
(12) Patent Application Publication
(10) Pub. No.: US 2020/0010707 A1
(43) Pub. Date: Jan. 9, 2020

(54) METHOD OF FINISHING A METALLIC CONDUCTIVE LAYER

(71) Applicants: National Research Council of Canada, Ottawa (CA); Groupe Graham International Inc., Lachine (CA)

(72) Inventors: Sylvie LAFRENIÈRE, Lac-Tremblant-Nord (CA); Bhavana DEORE, Ottawa (CA); Chantal PAQUET, Ottawa (CA); Arnold J. KELL, Ottawa (CA); Patrick Roland Lucien MALENFANT, Ottawa (CA)

(21) Appl. No.: 16/483,282

(22) PCT Filed: Feb. 8, 2018
(86) PCT No.: PCT/IB2018/050790

§ 371 Date: Aug. 2, 2019

Related U.S. Application Data
(60) Provisional application No. 62/456,310, filed on Feb. 8, 2017.

(51) Int. Cl. C09D 11/52; C09D 11/037; C09D 11/033; C09D 11/104; H05K 3/40; H05K 1/09; H05K 3/12; H05K 1/11; B41M 1/12

(52) U.S. Cl. CPC C09D 11/52; C09D 11/037; C09D 11/033; C09D 11/104; H05K 3/4007; H05K 2201/0391; H05K 3/1283; H05K 3/1216; H05K 1/111; B41M 1/12; H05K 2201/0338; H05K 1/092

(57) ABSTRACT

A process for finishing a conductive metallic layer (e.g. a layer of copper metal) involves coating a molecular silver ink on the conductive metallic layer and decomposing the silver ink to form a solderable coating of silver metal on the conductive metallic layer. The molecular silver ink includes a silver carboxylate, a carrier and a polymeric binder. The process is additive and enables the cost-effective formation of a silver metal finish on conductive metallic layers, which both protects the conductive metallic layer from oxidation and further corrosion and allows soldering with lead and lead-free solders.

### FIELD

This application relates to finishing a metallic conductive layer, in particular to methods of finishing a metallic conductive layer comprising a solderable metal for use in printed circuits, and to methods of soldering on the metallic conductive layer particularly in the production of printed circuits.

### BACKGROUND

Copper layers located on top and bottom sides of printed circuit boards (PCBs) oxidizes rapidly and the CuO/CuO₂ oxides produced on the surface inhibit the wetting action of solder on the copper pad. This phenomenon renders the copper solder layers unsuitable for electronics components assembly due to its inability to produce acceptable and reliable solder joints. The copper therefore requires a surface finish in order to render the PCB usable. The surface finish has two essential functions: first to protect the exposed copper from oxidation; and, second to provide a solderable surface when assembling (soldering) components to the printed circuit board. Several PCB surface finishes exist and vary in price, availability, shelf life, reliability and assembly processing. While each finish has its own benefits and limitations, in most cases the printed circuit board design, the field of application (medical, military, aerospace, industrial or other), the environmental exposure and the assembly processes will dictate the surface finish that is the most appropriate for the application.

For example, the copper top and bottom solder layers of a PCB can be protected from oxidation using Immersion tin or immersion silver processes. Silver immersion in particular is a process that offers good performance and superior surface finishes. In a silver immersion process, silver metal is selectively deposited on the copper surfaces that will need to be soldered and protected from oxidation and corrosion. Silver immersion yields a smooth uniform deposit on the copper that is approximately 8-15 μm thick. A surface finish having a flat topography is absolutely required to solder high density circuitry, like fine pitch ICs, high I/O BGAs, and very small electronics components. Also, immersion silver surface finish yield to acceptable PCB shelf-life of 6 months to 12 months depending on the PCBs storage conditions.

Actual silver immersion surface finishes are electrodeposited or electroless-plated onto exposed copper surfaces using silver ions or silver salts solutions. From a manufacturing standpoint, the process is very sensitive to silver salt concentration, solution PH, and requires automated process controls and measurements to maintain the deposition rate and the surface finish quality. The immersion silver process steps are plating of the board in tanks of agitated acidic solutions, followed by sonication and cleaning of the resulting PCB. Sulfur contamination, which is detrimental to forming a good solder joint, can occur during these steps. Another issue inherent to the actual process is that it uses a lot of water, generates toxic wastes and necessitates water decontamination facilities to treat the process effluents. Finally, employees working in these facilities must wear protection equipment for their safety.

Considering all the above, there is a need for an additive method that enables the formation of a silver surface finish that both protects a conductive metallic layer and allows soldering using lead and lead-free solders. Such an additive process would be a cost-effective method of finishing a solderable metal with silver.

### SUMMARY

In one aspect, there is provided a process for finishing a conductive metallic layer, the process comprising: coating a molecular silver ink on a conductive metallic layer, the molecular silver ink comprising a silver carboxylate, a carrier and a polymeric binder; and, decomposing the silver ink to form a solderable coating of silver metal on the conductive metallic layer.

In another aspect, there is provided a process for soldering on a conductive metallic layer, the process comprising: coating a molecular silver ink on a conductive metallic layer, the molecular silver ink comprising a silver carboxylate, a carrier and a polymeric binder; decomposing the silver ink to form a solderable coating of silver metal on the conductive metallic layer; and, applying a solder to the solderable silver metal coated on the conductive metallic layer to form a solder joint with the silver metal.

In another aspect, there is provided a layered material comprising a conductive metallic layer deposited on at least a portion of a surface of a substrate, the conductive metallic layer at least partially coated with a molecular ink comprising a silver carboxylate, a carrier, and a polymeric binder, the polymeric binder comprising a polyester, polyimide, polyether imide or any mixture thereof having functional groups that render the polymeric binder compatible with the carrier.

In another aspect, there is provided a use of a hydroxyl- and/or carboxyl-terminated polyester as a binder in a molecular ink.

The processes are additive and enable the formation of a silver metal finish on a conductive metallic layer, which both protects the conductive metallic layer and allows soldering with lead and lead-free solders. The process is cost-effective.

Further features will be described or will become apparent in the course of the following detailed description. It should be understood that each feature described herein may be utilized in any combination with any one or more of the other described features, and that each feature does not necessarily rely on the presence of another feature except where evident to one of skill in the art.

### BRIEF DESCRIPTION OF THE DRAWINGS

For clearer understanding, preferred embodiments will now be described in detail by way of example, with reference to the accompanying drawings, in which:

FIG. 1A depicts a schematic diagram (left) and an optical image (right) of a silver-coated copper surface on which a solder has been applied. The silver coating was formed by printing a molecular silver ink on the copper surface followed by sintering. The silver coating allows the formation of a stable and strong solder joint.

FIG. 1B depicts a schematic diagram (left) and an optical image (right) of a bare copper surface on which a solder has been applied. The solder does not wet the copper surface properly resulting in a solder joint unacceptable as per IPC A-610.

FIG. 2A shows a cross-sectional SEM image showing the intermetallic layer between the solder and copper foil with a silver finish solder

FIGS. 2B and 2C show cross-sectional SEM images with EDS analysis of the atomic composition along the layer of solder, the intermetallic layer and copper foil.

### DETAILED DESCRIPTION

The conductive metallic layer to be finished, or finished and soldered, may be in any physical form, for example as a free-standing structure such as a sheet (e.g. foil, plate), a wire, a sphere (e.g. ball bearing) and the like, or as a structure deposited on a substrate such as a thin sheet, a trace, a pillar, and the like deposited on at least a portion of a substrate. In the fabrication of printed circuit boards (PCBs) or other electronic structures, conductive metallic layer may be deposited on a suitable substrate, often in the form of a trace. The conductive metallic layer may comprise a solderable metal, for example copper, gold, tin, palladium, aluminum or alloys thereof. The process is particularly useful for copper or copper alloys.

Suitable substrates may include, for example polyethylene terephthalate (PET) (e.g. Melinex™), polyolefin (e.g. silica-filled polyolefin (Teslin™)), polydimethylsiloxane (PDMS), polystyrene, acrylonitrile/butadiene/styrene, polycarbonate, polyimide (e.g. Kapton™), thermoplastic polyurethane (TPU), silicone membranes, wool, silk, cotton, flax, jute, modal, bamboo, nylon, polyester, acrylic, aramid, spandex, polylactide, paper, glass, metal, dielectric coatings, among others.

Deposition of the conductive metallic layer on the substrate may be achieved by any suitable method, for example, electrodeposition (e.g. electroplating), deposition and sintering of molecular inks. Rigid and flex circuits are mainly manufactured using a pure metal foil laminated on a surface with the use of an adhesive and heat followed by etching to produce the traces and patterns needed.

When the conductive metallic layer is deposited or laminated on a rigid or flexible substrate, a layered material comprising a layer of solderable metal on at least a portion of a surface of the substrate may be produced. The conductive metallic layer is preferably fully coated with the molecular silver ink because IPC A-610 standards require no exposed copper on a rigid or flex circuit to prevent corrosion.

The ink may be coated on the conductive metal layer by any suitable method, for example printing. Printing methods may include, for example, screen printing, stencilling, inkjet printing, flexography printing, gravure printing, off-set printing, stamp printing, airbrushing, aerosol printing, typesetting, or any other method. It is an advantage of the process that an additive method such as screen printing or stenciling are particularly useful. Additive coating methods permit the use of additive manufacturing techniques, for example on printed circuit boards.

After coating the conductive metallic layer with the molecular silver ink, the ink on the conductive metallic layer may be dried and decomposed to form a silver metal coating on the conductive metallic layer to finish the conductive metallic layer. Drying and decomposing the silver carboxylate on the conductive metallic layer forms a conductive solderable silver metal coating on the conductive metallic layer. Drying and decomposition may be accomplished by any suitable technique, where the techniques and conditions are guided by the type of substrate and the type of silver carboxylate. For example, drying the ink and decomposing the silver carboxylate may be accomplished by heating and/or photonic sintering.

In one technique, heating the substrate dries and sinters the silver carboxylate coating to form metallic silver. It is an advantage that heating may be performed at a relatively high temperature range for longer periods of time. Heating may be performed at a temperature of about 150° C. or higher, or 165° C. or higher, or 175° C. or higher, or 180° C. or higher, or 185° C. or higher, or 200° C. or higher, or 220° C. or higher, or 230° C. or higher, or 240° C. or higher while producing relatively highly conductive silver coatings that have good mechanical properties. In one embodiment, the temperature is in a range of about 200° C. to about 250° C. Heating is preferably performed for a time in a range of about 1-180 minutes, for example 5-120 minutes, or 5-60 minutes. Heating is performed at a sufficient balance between temperature and time to sinter the ink to form solderable conductive silver coatings. Improved thermal stability of the ink permits heating for longer periods of time, for example up to 1 hour or more. The type of heating apparatus also factors into the temperature and time required for sintering. Sintering may be performed with the substrate under an oxidizing atmosphere (e.g. air) or an inert atmosphere (e.g. nitrogen and/or argon gas).

In another technique, a photonic sintering system may feature a high intensity lamp (e.g. a pulsed xenon lamp) that delivers a broadband spectrum of light. The lamp may deliver about 5-30 J/cm² in energy to the traces. Pulse widths are preferably in a range of about 0.58-1.5 ms. Photonic sintering may be performed under ambient conditions (e.g. in air). Photonic sintering is especially suited when polyethylene terephthalate or polyimide substrates are used.

On a substrate where conductive metal traces are electrically disconnected or where other components are to be added, interconnections between traces and electronic components can be made by using a solderable surface finish and a solder. Soldering is performed after the silver ink is sintered into a silver film. It is an advantage that the molecular silver ink is formulated with a polymeric binder that has excellent adhesion to the conductive metallic layer and can withstand the higher temperatures at which the solder is applied. As a result, the molecular silver ink can produce smooth electrically conductive silver traces, which is desirable for proper formation of solder joints. The ability to generate strong solder joints is particularly useful when employing additive manufacturing techniques on printed circuit boards. The molecular silver ink provides a silver finish that generates a strong solder interconnection. Soldered components have shown acceptable shear strength, and adhesion force of printed traces and features is not affected by the soldering process. The conductivity of the interconnections produced using a lead-free soldering process and the molecular ink printed on a conductive metal surface have been measured using a shear force apparatus and the latter showed much better shear force results than interconnections made using conductive epoxies. The conductivity of the interconnection made using the molecular ink and a lead-free solder is comparable to the conductivity of an interconnection made using a surface finish produced by electro-deposition, or plating, and the same soldering process.

Soldering techniques for attaching components to a printed circuit board are generally known in the art and utilize such tools as solder, soldering irons, fluxes, solder wicks and flux remover. While lead-based solders may be used (e.g. tin/lead solder (e.g. 60 Sn/40 Pb or 63 Sn/37 Pb), lead-free solders (e.g. SAC305 (96.5 Sn/3 Ag/0.5 Cu) are generally preferred. Lead-free solders may contain tin, copper, silver, bismuth, indium, zinc, antimony, and traces of other metals. Solders typically melt in a range of about 90° C. to 450° C., for example about 200° C. to about 300° C. For electronic soldering, rosin solders are used instead of acid core solders. The temperature of the soldering processes used preferably does not exceed 260° C. because that temperature is the maximum temperature recommended for lead-free printed circuits boards and components in the IPC standards followed by the electronics interconnection industry.

A finished substrate, or a finished and soldered substrate, may be incorporated into an electronic device, for example electrical circuits (e.g. printed circuit boards (PCBs), conductive bus bars (e.g. for photovoltaic cells), sensors (e.g. touch sensors, wearable sensors), antennae (e.g. RFID antennae), thin film transistors, diodes, smart packaging (e.g. smart drug packaging), conformable inserts in equipment and/or vehicles, and multilayer circuits and MIM devices including low pass filters, frequency selective surfaces, transistors and antenna on conformable surfaces that can withstand high temperatures.

The molecular silver ink comprises a silver carboxylate, a solvent, and a polymeric binder.

Silver carboxylates comprise a silver ion and an organic group containing a carboxylic acid moiety. The carboxylate preferably comprises from 1 to 20 carbon atoms, more preferably from 6 to 15 carbon atoms, even more preferably from 8 to 12 carbon atoms, for example 10 carbon atoms. The carboxylate is preferably an alkanoate. The silver carboxylate is preferably a silver salt of an alkanoic acid. Some non-limiting examples of preferred silver carboxylates are silver ethylhexanoate, silver neodecanoate, silver benzoate, silver phenylacetate, silver isobutyrylacetate, silver benzoylacetate, silver oxalate, silver pivalate and derivatives thereof and any mixtures thereof. Silver neodecanoate is particularly preferred. One or more than one silver carboxylate may be in the ink. The silver carboxylate is preferably dispersed in the ink. Preferably, the ink does not contain flakes or other particles of metallic silver material.

The silver carboxylate is preferably present in the ink in an amount to provide a silver loading of about 19 wt % or more in the ink, based on total weight of the ink. More preferably, the silver carboxylate provides a silver loading of about 23 wt % or more, or about 24 wt % or more, or about 25 wt % or more, or about 27 wt % or more, or about 31 wt % or more, or about 32 wt % or more. When the silver carboxylate is silver neodecanoate, the silver neodecanoate may be preferably present in the ink in an amount of about 50 wt % or more, based on total weight of the ink, or about 60 wt % or more, or about 65 wt % or more, or about 70 wt % of more, or about 80 wt % or more.

The carrier is preferably compatible with one or both of the silver salt or polymeric binder. The carrier is preferably compatible with both the silver salt and polymeric binder. The silver salt and/or polymeric binder are preferably dispersible, for example soluble, in the carrier. The carrier is preferably a solvent. The solvent is preferably an organic solvent, more preferably a non-aromatic organic solvent. Non-aromatic organic solvents include, for example, terpenes (e.g. terpene alcohols), glycol ethers (e.g. dipropylene glycol methyl ether), alcohols (e.g. methylcyclohexanols, octanols, heptanols), carbitols (e.g. 2-(2-ethoxyethoxy)ethanol) or any mixture thereof. The solvent preferably comprises a terpene, more preferably a terpene alcohol. Terpene alcohols may comprise monoterpene alcohols, sesquiterpene alcohols and the like. Monoterpene alcohols, for example terpineols, geraniol, etc., are preferred. Terpineols, for example α-terpineol, β-terpineol, γ-terpineol, and terpinen-4-ol are particularly preferred. Especially preferred is α-terpineol.

The carrier may be present in the ink in any suitable amount, preferably in a range of about 1 wt % to about 50 wt %, based on total weight of the ink. More preferably, the amount is in a range of about 5 wt % to about 50 wt %, or about 10 wt % to about 40 wt %.

The polymeric binder preferably comprises polyester, polyimide, polyether imide, polyether (such as for e.g. ethyl cellulose) or any mixture thereof. In one embodiment, the polymeric binder comprises polyester, polyimide, polyether imide or any mixture thereof. The polymeric binder may have functional groups that render the polymeric binder compatible with the carrier. Preferably, the polymeric binder is dispersible, for example soluble, in the carrier. Thus, a mixture of the polymeric binder in the carrier does not lead to significant phase separation. Functional groups that render the polymeric binder compatible with the carrier are preferably polar groups capable of participating in hydrogen bonding, for example one or more of hydroxyl, carboxyl, amino and sulfonyl groups. Preferably, the polymeric binder comprises terminal hydroxyl and/or carboxyl groups. In one embodiment, the polymeric binder preferably comprises a polyester having functional groups that render the polyester compatible with the carrier. More preferably, the polymeric binder comprises a hydroxyl- and/or carboxyl-terminated polyester.

The polymeric binder may be present in the ink in any suitable amount, preferably in a range of about 0.1 wt % to about 5 wt %, based on total weight of the ink. More preferably, the amount is in a range of about 0.5 wt % to about 3 wt %, or about 1 wt % to about 2 wt %.

In one embodiment, the molecular ink consists of a silver carboxylate, a carrier, and a polymeric binder comprising a hydroxyl- and/or carboxyl-terminated polyester.

### EXAMPLES

### Example 1

### Silver Neodecanoate Ink with Polyester Binder

A silver neodecanoate (AgND)-based ink (l1) was formulated as described in Table 1. The ink was prepared by combining all components and mixing in a plenary mixer until the solution was homogenous.

TABLE 1

| Ink Component | Ink I1 |
|---|---|
| silver neodecanoate (wt %) | 60 |
| Rokrapol ™ 7075 (wt %) | 1.6 |
| terpineol (wt %) | 38.4 |

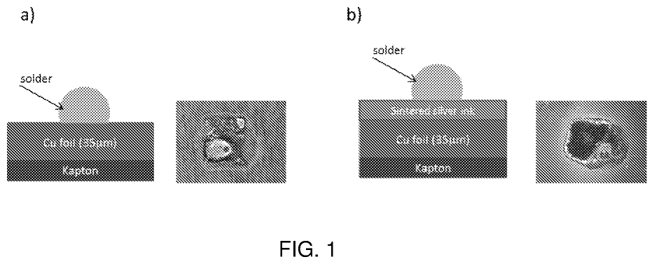

With reference to FIG. 1A and FIG. 1B, a layer of the silver ink was stenciled on to a first portion of a 35 μm thick copper foil 3 deposited on a sheet 1 of Kapton™ HPP-ST. The stenciled traces were thermally sintered under nitrogen at reflow temperatures (T) varying from 230° C. for 15 minutes (sample temperature) using the heating programs described in Table 2 to produce a layer 4 of silver on the copper foil 3. The temperatures quoted are those measured by a thermocouple attached to the Kapton™ substrate.

TABLE 2

| Zone | Front | Time, sec |
|---|---|---|
| Pre-heat 1 | 100° C. | 300 |
| Pre-heat 2 | 130° C. | 300 |
| Soak | 160° C. | 300 |
| Reflow | 230° C. | 2700 |
| Cool | 60° C. | 300 |

Solder paste 5 was applied to the layer 4 (FIG. 1A) and directly to the copper foil 3 (FIG. 1B). A lead-free, no-clean and halogen-free solder paste (Loctite™ GC10 SAC305T4 885V 52U) was applied to the copper coated film using a stencil 5 mil in thickness. The solder was made to reflow using the temperature program described in Table 3. The temperatures quoted are those measured by a thermocouple attached to the Kapton™ substrate.

TABLE 3

| Zone | Temperature | Time, sec |
|---|---|---|
| Pre-heat | 50° C. | 40 |
| Soak | 150° C. | 140 |
| Reflow | 230° C. | 90 |
| Cool | 30° C. | 60 |

As seen in the optical image (right) in FIG. 1A, the silver coating allows the formation of a stable and strong solder joint. In contrast, as seen in the optical image right in FIG. 1B, the solder does not wet the copper surface properly resulting in an unacceptable solder joint as per IPC A-610 standard. This advantage of using the silver molecular ink as a surface finish is also reflected in the differences in solder contact angle in the copper foil in comparison to the copper foil containing the silver finish. As highlighted in Table 4, the solder contact angle is significantly lower when the silver finish is present on the copper foil (13° vs. 24°). In addition, the solder shape retention is also better when the silver finish is present on the copper foil (Table 4).

TABLE 4
Contact angle and shape retention of solder on copper
foil and copper foil with a silver finish

| | contact | shape |
|---|---|---|
| ink | angle | retention |
| Cu foil control | 28 | fair |
| (no Ag) | | |
| Cu foil with | 13 | excellent |
| silver finish | | |

### Example 2

### Characterization of the Solder Joint on Silver Finished Copper Foil

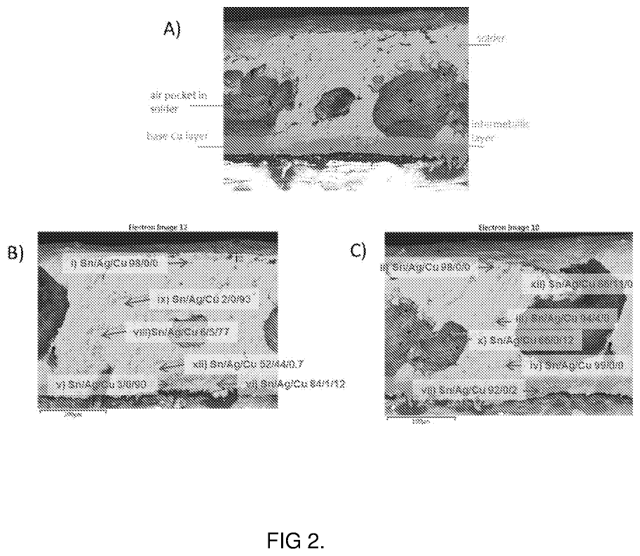

A 4 μm surface finish of the silver molecular ink was printed onto a 35 μm layer of copper foil on Kapton. Solder (SAC305) was subsequently deposited onto the surface of the resulting silver finish and processed in a reflow oven as described above. There is strong visual evidence that an intermetallic is formed between the copper foil and the solder following reflow (FIG. 2A). The elemental composition of SAC 305 is 96.5% Sn (tin), 3.0% Ag (silver) and 0.5% Cu (copper), and portions of the resulting solder joint has an elemental composition similar to that of SAC305 (i, ii, iii and iv). There is also evidence that an intermetallic layer is formed as highlighted in FIGS. 2B) and 2C), where tin from the SAC 305 solder has diffused into the copper foil (v, vi and vii) as evidenced by the presence of tin in the copper foil following EDS analysis. In addition, the relative proportion of copper (viii, ix, x) and silver (xi and xii) in the solder layer is higher than that of the SAC 305 itself again suggesting that an intermetallic is formed. The diffusion of the Sn into the copper layer and Cu/Ag into solder helps to facilitate the formation of a strong bond between the solder and the copper foil and thus a strong bond between the circuit and the electronic component to be attached.

### Example 3

### Silver Neodecanoate Ink with Ethyl Cellulose Binder

A copper foil coated with a pressure sensitive adhesive laminated on a tape was placed on a polyimide film (DuPont, Kapton™). The copper foil was then cleaned with isopropanol. An ink comprising 52.1 wt % (g/g) silver neodecanoate, 4.2 wt % (g/g) ethyl cellulose, 12 wt % (g/g) octanol and 35.9 wt % (g/g) diethylbenzene was printed on top of the copper. The sample was sintered at 250° C. for 15 minutes. A lead-free Multicore Loctite™ tacky flux paste was applied to the silver-coated copper. A light emitting diode (LED) was placed on the silver-coated copper and soldered for 3 seconds using a SAC305 core solder wire by heating a lead-free solder tip to 400 to 425° C. and allowing the solder wire to reflux to a minimal solder temperature of 230° C. The maximum temperature of the substrate and the component during this step was 260° C. and 250° C., respectively. The area was cleaned with isopropyl alcohol. The LED was tested by applying 3V. The interconnection was tested with a shear test (IEC 62137-2) and inspected using IPC-A-610 Class 2. Shear bond testing showed a bond strength of 10 lbs.

The novel features will become apparent to those of skill in the art upon examination of the description. It should be understood, however, that the scope of the claims should not be limited by the embodiments, but should be given the broadest interpretation consistent with the wording of the claims and the specification as a whole.

1. A process for finishing a conductive metallic layer, the process comprising: coating a molecular silver ink on the conductive metallic layer, the molecular silver ink comprising a silver carboxylate, a carrier and a polymeric binder; and, decomposing the silver ink to form a solderable coating of silver metal on the conductive metallic layer.

2. A process for soldering on a conductive metallic layer, the process comprising: coating a molecular silver ink on a conductive metallic layer, the molecular silver ink comprising a silver carboxylate, a carrier and a polymeric binder; decomposing the silver ink to form a solderable coating of silver metal on the conductive metallic layer; and, applying a solder to the solderable silver metal coated on the conductive metallic layer to form a solder joint with the silver metal.

3. The process according to claim 1 or 2, wherein the conductive metallic layer comprises copper, gold, tin, palladium, aluminum or an alloy thereof.

4. The process according to any one of claims 1 to 3, wherein the polymeric binder comprises polyester, polyimide, polyether imide, polyether or any mixture thereof.

5. The process according to any one of claims 1 to 4, wherein the polymeric binder comprises functional groups that render the polymeric binder compatible with the carrier.

6. The process according to any one of claims 1 to 3, wherein the polymeric binder comprises a hydroxyl- and/or carboxyl-terminated polyester.

7. The process according to any one of claims 1 to 6, wherein the silver carboxylate is in the ink in an amount that provides a silver loading in the ink of about 19 wt % or more, based on total weight of the ink.

8. The process according to any one of claims 1 to 6, wherein the silver carboxylate is in the ink in an amount that provides a silver loading in the ink of about 24 wt % or more, based on total weight of the ink.

9. The process according to any one of claims 1 to 8, wherein the silver carboxylate comprises silver neodecanoate.

10. The process according to claim 9, wherein the silver neodecanoate is present in the ink in an amount of about 60 wt % or more, based on total weight of the ink.

11. The process according to claim 9, wherein the silver neodecanoate is present in the ink in an amount of about 80 wt % or more, based on total weight of the ink.

12. The process according to any one of claims 1 to 11, wherein the polymeric binder is present in the ink in an amount of about 0.1 wt % to about 5 wt %, based on total weight of the ink.

13. The process according to any one of claims 1 to 12, wherein the carrier comprises an organic solvent.

14. The process according to claim 13, wherein the solvent comprises α-terpineol.

15. The process according to any one of claims 1 to 14, wherein the carrier is present in the ink in an amount in a range of about 1 wt % to about 50 wt %, based on total weight of the ink.

16. The process according to any one of claims 1 to 14, wherein the carrier is present in the ink in an amount in a range of about 10 wt % to about 40 wt %, based on total weight of the ink.

17. The process according to any one of claims 1 to 16, wherein the conductive metallic layer is deposited on a substrate.

18. The process according to claim 17, wherein the substrate comprises polyethylene terephthalate, polyolefin, polydimethylsiloxane, polystyrene, acrylonitrile/butadiene/styrene, polycarbonate, polyimide, thermoplastic polyurethane, a silicone membrane, wool, silk, cotton, flax, jute, modal, bamboo, nylon, polyester, acrylic, aramid, spandex, polylactide, paper, glass, metal or a dielectric coating.

19. The process according to any one of claims 1 to 18, wherein coating the molecular silver ink on the conductive metallic layer comprises printing.

20. The process according to claim 19, wherein the printing comprises screen printing or stenciling.

21. The process according to any one of claims 1 to 20, wherein the decomposing of the molecular silver ink comprises sintering of the molecular silver ink.

22. A layered material comprising a conductive metallic layer deposited on at least a portion of a surface of a substrate, the conductive metallic layer at least partially coated with a molecular ink comprising a silver carboxylate, a carrier, and a polymeric binder, the polymeric binder comprising a polyester, polyimide, polyether imide or any mixture thereof having functional groups that render the polymeric binder compatible with the carrier.
